(19) United States
(12) Patent Application Publication
(10) Pub. No.: US 2025/0300054 A1
(43) Pub. Date: Sep. 25, 2025

(54) CONFORMALLY PLATED THROUGH-VIAS IN GLASS

(71) Applicant: Intel Corporation, Santa Clara, CA (US)

(72) Inventors: Brandon Christian Marin, Gilbert, AZ (US); Srinivas Venkata Ramanuja Pietambaram, Chandler, AZ (US); Mitchell Ian Page, Mesa, AZ (US)

(73) Assignee: Intel Corporation, Santa Clara, CA (US)

(21) Appl. No.: 18/613,757

(22) Filed: Mar. 22, 2024

(51) Int. Cl. H01L 23/498; H01L 21/48; H01L 23/538

(52) U.S. Cl. CPC H01L 23/49827; H01L 21/486; H01L 23/5384

(57) ABSTRACT

Apparatus and methods for conformally plated through-holes in glass. The apparatus includes a through-hole or through-glass via (TGV) formed in a layer of glass, extending downward from an upper surface, with an axis that is orthogonal to the upper surface. The TGV is defined by a shape similar to an hourglass, with a first diameter at the upper surface and the first diameter at the lower surface, and a smaller second diameter therebetween. The periphery of the TGV is described as a sidewall. The sidewall is plated with a thin conformal conductive material from the upper surface to the lower surface, thereby forming a cavity therein. The cavity can be bridged by the conductive material at the second diameter. An insulating material is in the cavity. A conductive contact can extend across the TGV at the upper surface and electrically connect with the conductive material.

### BACKGROUND

A layer of glass is often used to provide better mechanical/dimensional stability, rigidity, and to improve routing density in a semiconductor package when compared to traditional epoxy-glass fiber composite materials. In order to route signals from an upper surface of the layer of glass to a lower surface, the layer of glass is generally perforated with through vias, or “through-glass vias (TGVs).” However, the brittle quality of glass and effective copper deposition in the TGVs continue to present technical challenges in fabrication and operation. Accordingly, improved architectures and methods for routing signals through the glass layers are desired.

### BRIEF DESCRIPTION OF THE DRAWINGS

FIG. 1 provides simplified cross-sectional illustrations of embodiments of conformally plated through-glass vias, in accordance with various embodiments.

FIGS. 2-5 illustrate various exemplary stages of fabrication of conformally plated through-glass vias, in accordance with various embodiments.

FIGS. 6-7 illustrate exemplary use cases for conformally plated through-glass vias, in accordance with various embodiments.

FIG. 8 illustrates an example method for conformally plated through-glass vias, in accordance with various embodiments.

FIG. 9 is a top view of a wafer and dies that may be included in a microelectronic assembly, in accordance with any of the embodiments disclosed herein.

FIG. 10 is a simplified cross-sectional side view showing an implementation of an integrated circuit on a die that may be included in various embodiments, in accordance with any of the embodiments disclosed herein.

FIG. 11 is a cross-sectional side view of a microelectronic assembly that may include any of the embodiments disclosed herein.

FIG. 12 is a block diagram of an example electrical device that may include any of the embodiments disclosed herein.

### DETAILED DESCRIPTION

A semiconductor package may include a multi-layer substrate with a “glass core” or layer of glass sandwiched therebetween. The layer of glass has perforations therethrough (also called through-vias or through-glass vias (TGVs)) to accommodate routing electrical signals between the silicon substrate on its upper and lower surfaces. The layer of glass provides mechanical/directional stability and rigidity in a semiconductor package, and can increase routing density, however, the brittle quality of glass and difficulties with effective copper deposition in the TGVs continue to present technical challenges in fabrication and operation.

Some solutions have deposited a buffer or liner layer on the sidewalls of the TGVs to improve copper deposition in the TGVs. However, these solutions are vulnerable to bending stress and temperature stress. Additionally, although the TGVs are often illustrated with perpendicular walls, in practice they are more likely to taper from the upper surface to the midpoint and from the lower surface to the midpoint, exhibiting an hourglass shape. This taper, when filled with a conductive material, creates a “pinch point” at the midpoint. The pinch point phenomenon can adversely limit performance and power density.

Embodiments described herein provide a technical solution to these technical challenges in the form of conformal plated through-glass vias. Practice of the architectures and methods described herein can be readily detected with SEM and/or TEM images as described below. These concepts are developed in more detail below.

Example embodiments are hereinafter described in conjunction with the following drawing figures, wherein like numerals denote like elements. Unless otherwise stated, figures are not necessarily to scale but may be relied on for spatial orientation and relative positioning of features. As may be appreciated, certain terminology, such as “ceiling” and “floor”, as well as “upper,”, “uppermost”, “lower,” “above,” “below,” “bottom,” and “top” refer to directions based on viewing the Figures to which reference is made. Further, terms such as “front,” “back,” “rear,”, “side”, “vertical”, and “horizontal” may describe the orientation and/or location of portions of the component within a consistent but arbitrary frame of reference which is made clear by reference to the text and the associated Figures describing the component under discussion. Such terminology may include the words specifically mentioned above, derivatives thereof, and words of similar import.

As used herein, the term “adjacent” refers to layers or components that are in direct physical contact with each other, with no layers or components in between them. For example, a layer X that is adjacent to a layer Y refers to a layer that is in direct physical contact with layer Y. In contrast, as used herein, the phrase(s) “located on” (in the alternative, “located under,” “located above/over,” or “located next to,” in the context of a first layer or component located on a second layer or component) includes (i) configurations in which the first layer or component is directly physically attached to the second layer (i.e., adjacent), and (ii) component and configurations in which the first layer or component is attached (e.g. coupled) to the second layer or component via one or more intervening layers or components.

The following detailed description is not intended to limit the application and use of the disclosed technologies. It may be evident that the novel embodiments can be practiced without every detail described herein. For the sake of brevity, well-known structures and devices may be shown in block diagram form to facilitate a description thereof.

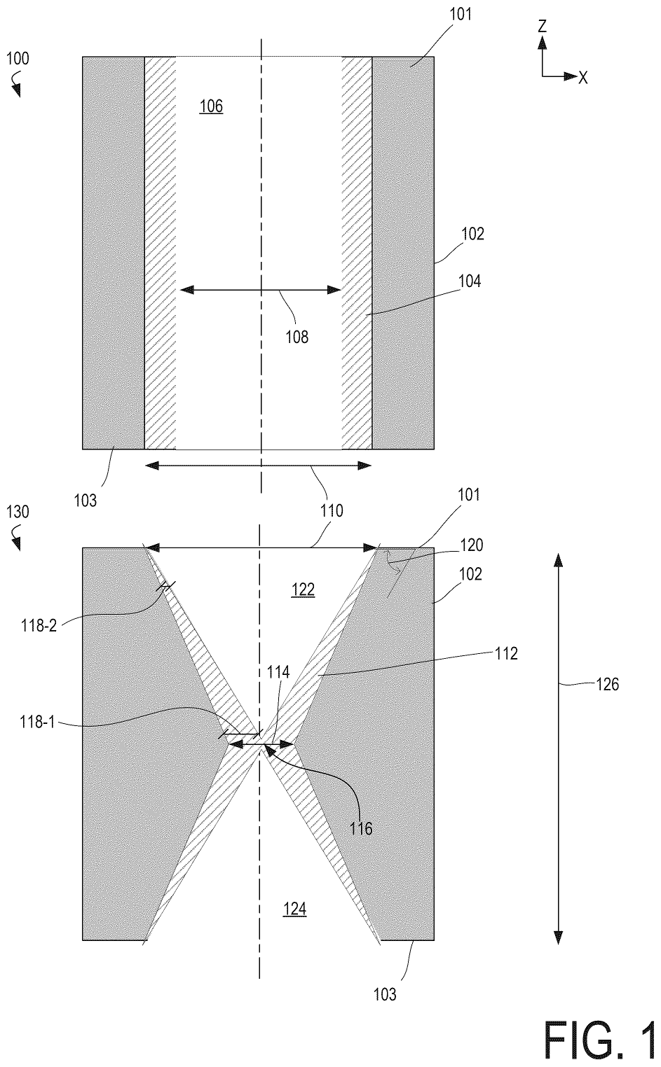

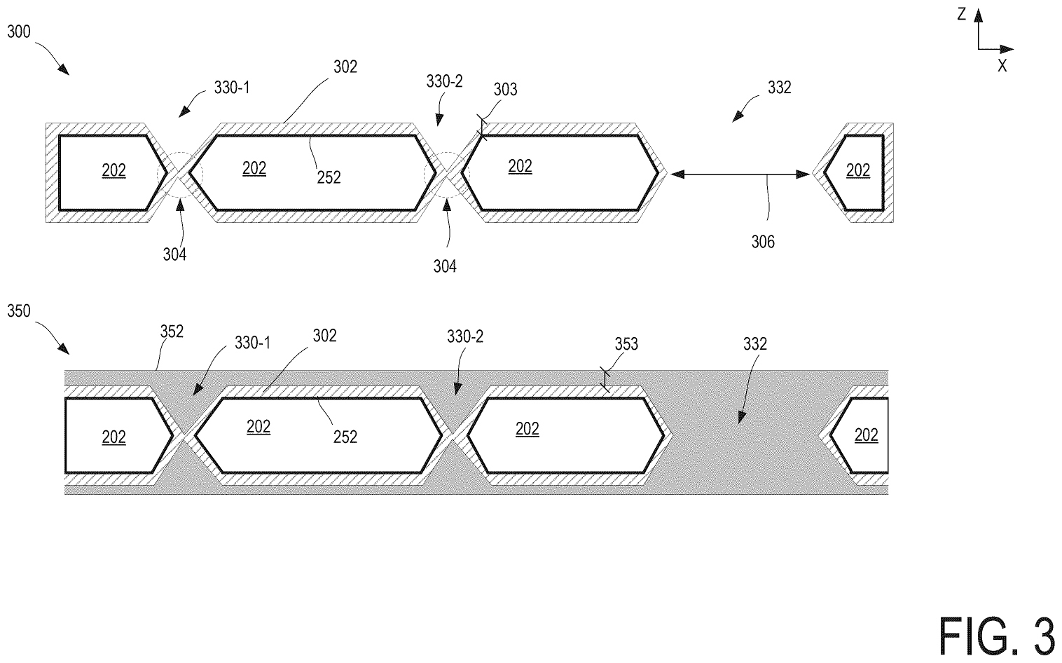

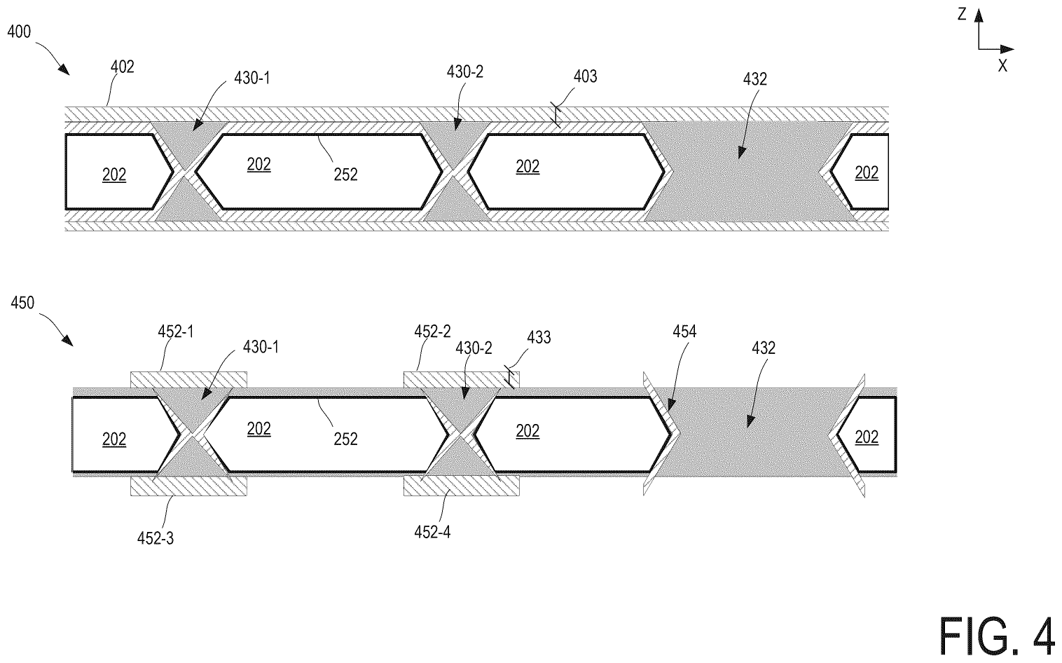

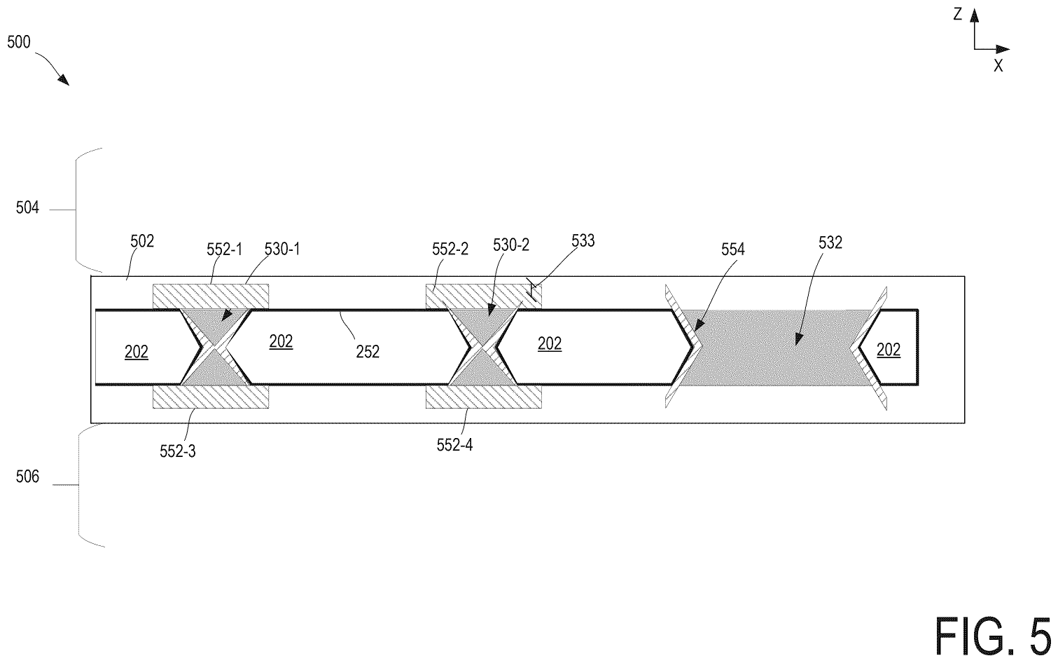

FIGS. 1-7 include many objects that are repeated. Unless otherwise stated, like objects are intended to perform the same function or be the same feature across images, whether labeled or not. Additionally, while the objects in FIGS. 1-7 are not to scale, various relationships and orientations shown in the images are intentional, as described herein.

FIG. 1 provides simplified cross-sectional illustrations of embodiments of conformally plated through-glass vias. The layer of glass 102 or “glass core” may be patterned with a plurality of through-holes, also referred to as through-glass vias (TGVs). Embodiment 100 and embodiment 130 illustrate one of at least one TGVs that may be in the layer of glass 102. The layer of glass 102 has an upper surface 101 and a lower surface 103. The layer of glass 102 may have a thickness 126 (Z height) in a range of about 20 microns to about 1.5 millimeter, +/−10%.

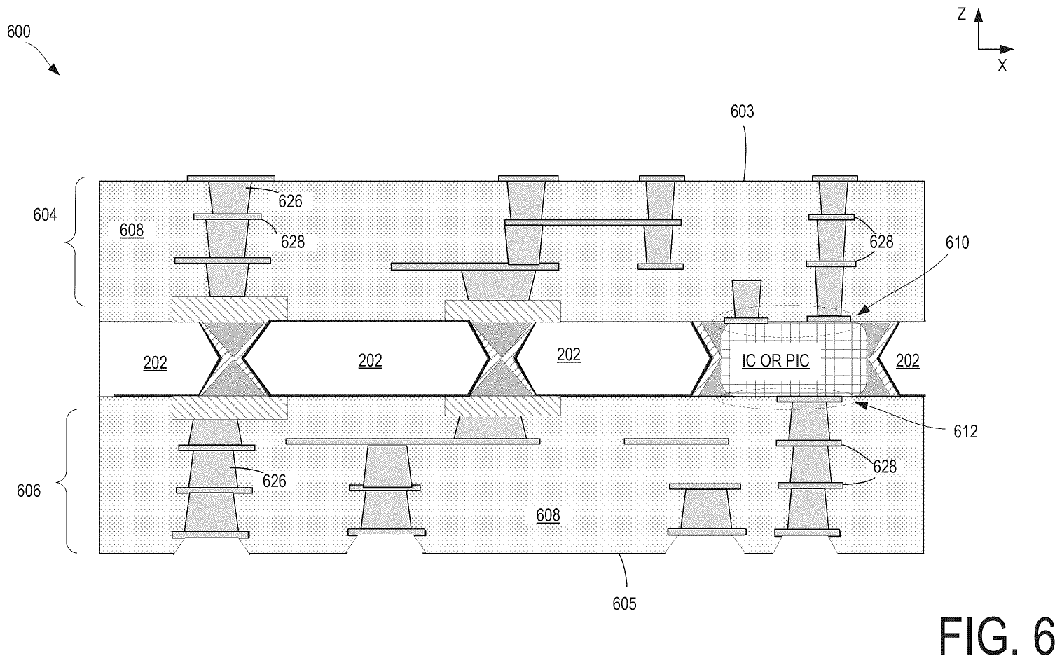

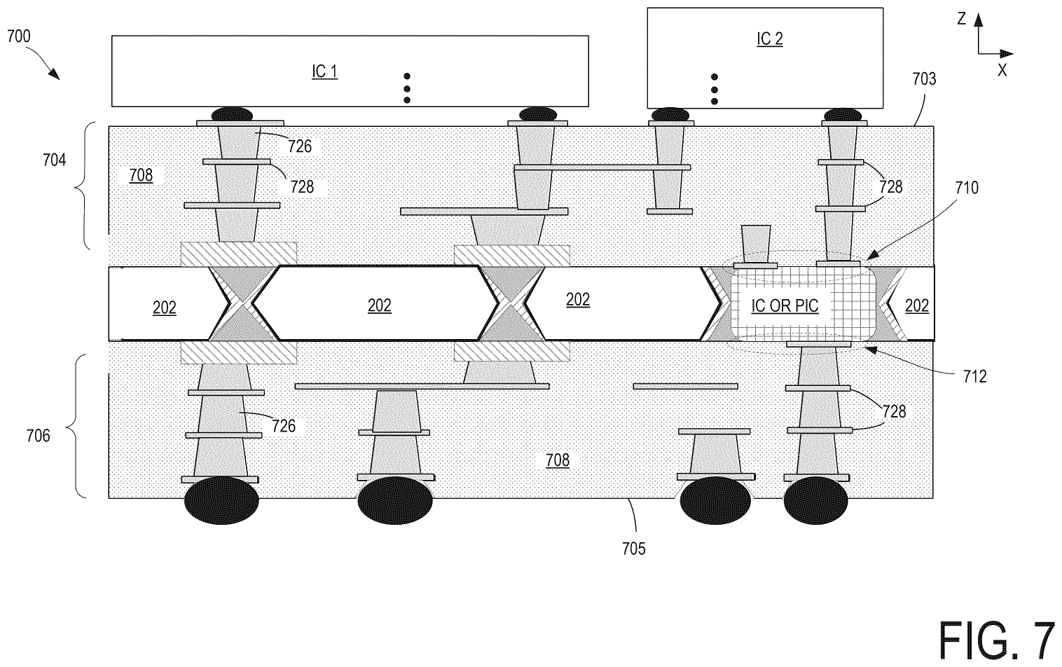

The layer of glass 102 may comprise glass, (as used herein, glass can be an alkali-free alkaline earth boro-aluminosicilate glass, such as a glass comprising aluminum, oxygen, boron, silicon, and an alkaline-earth metal (e.g., beryllium, magnesium, calcium, strontium, barium, radium, such as a glass comprising SiO2, Al2O3, B2O3, and MgO), or a photosensitive glass (photomachineable or photostructurable glass). In some embodiments, a photosensitive glass can be a glass that belongs to the lithium-silicate family of glass (e.g., a glass comprising lithium, silicon, and oxygen) comprising metallic particles, such as gold, silver, or other suitable metallic particles. In some embodiments, the layer of glass 102 or glass core may comprise multiple glass sheets bonded together with an adhesion layer. In various embodiments, e.g., in a substrate (e.g., see the illustrations in FIG. 6 and FIG. 7) having a Z height (thickness) in a range of about 0.1 millimeters (mm) to 15 mm.

At least one through-hole or through-glass via (TGV) is formed in the layer of glass 102. The through-holes extend downward from the upper surface 101 to the lower surface 103, with an axis that is orthogonal to the upper surface, as shown. The TGVs are volumes in which glass is removed and conductive materials are placed in the volumes, sufficient to enable electrical communication from an upper surface 101 to a lower surface 103. Accordingly, the through-holes are characterized by a sidewall, associated with a first diameter 110 at the upper surface 101 and the first diameter 110 at the lower surface 103. As illustrated in embodiments 100 and 130, the axis of the TGV is substantially perpendicular to the upper surface 101 of the layer of glass 102.

The shape of the TGV reflects a technology used to create it. In embodiment 130, the sidewall has a slope (angle 120) measured from a plane of the upper surface 101, in which the through-hole narrows as one traces toward a midpoint, the midpoint having a second diameter 114 that is smaller than the first diameter. In an embodiment, the second diameter is at least 10% smaller than the first diameter and can grow to 100% in ideal cases. The slope on the sidewall in embodiment 130 can be a result of using a laser etch to create the TGV: in this approach, the upper surface 101 is laser etched to approximately the midpoint and the lower surface is similarly laser etched to the midpoint. This results in a somewhat hourglass-shaped TGV, as illustrated, and yields a corresponding slope to the sidewall on the lower half of the TGV. The midpoint may be halfway between the upper and lower surface, plus or minus 15%. In contrast, in an idealized cylindrical TGV, as illustrated in embodiment 100, the through-hole has the first diameter 110 continuously from the upper surface 101 to the lower surface 103.

A conductive material 104 is conformal to the sidewall in the cavity, and adjacent to the non-conductive liner layer 252 between the copper (conductive material) and the glass. The conductive material 104 is continuous from the upper surface to the lower surface. The conductive material does not completely fill the TGV. In embodiment 100, the conductive material has a thickness that remains the same from the upper surface to the lower surface, that thickness being represented by first diameter 110 minus diameter 108, wherein the diameter 108 is the diameter of the cavity 106 that extends continuously from the upper surface 101 to the lower surface 103. The conductive material forms at least one cavity within the TGV.

In practice, technologies used to form the TGVs may more often create the sidewall shape of embodiment 130. In embodiment 130, the sidewalls are tapered or sloped inward at angle 120, as shown. This can be from using a laser to create the TGV, and the laser tapers when it goes through a material. Also, in embodiment 130, the thickness 118 of the conductive material 112 varies from the upper surface 101 to the midpoint to the lower surface 103; this is illustrated with thickness 118-1 near the midpoint and thickness 118-2 at the upper surface 101. The conductive material 112 forms a bridge 116 at the midpoint, as shown. The bridge 116 forms a floor to the cavity 122 and thereby also forms a second cavity 124 in the TGV volume, between the bridge 116 and the lower surface 103.

In practice, the TGVs and optional cavities similarly created in the layer of glass may have an insulating material inside, and the TGVs may have a conductive contact or conductive pad extending across them and electrically attached to the conductive material of the sidewall. An explanation of the fabrication of these features and further fabrication steps follows in connection with FIGS. 1-8.

Practice of these embodiments can be identified by visually inspecting TEM or SEM images of cross-sectional views, as illustrated in embodiment 130, and observing the thickness change in the conductive material 112 (measured moving up and down the Z axis, as illustrated and described), and the bridge 116 created by the conductive material 112, also as illustrated and described.

Moreover, various embodiments can be identified by visually inspecting TEM or SEM images of top-down or plan views. For example, comparing a planar slice made horizontally at A, at B, and at C, in embodiment 130, would reveal rings of the conductive material 112 with differing outer diameters and either with an inner diameter or solid, as it would be at the bridge 116. A calculation of the cross-sectional area of each of these images (at A, B, and C) would result in the same number plus or minus 15%.

These visually observable features shown in embodiment 130 are advantageous because having conductive material at the surface of the glass is generally positively associated with the mechanical stress experienced there, e.g., the more copper at or near the surface of the glass, the more stress, generally. Embodiments advantageously reduce the amount of conductive material at the upper surface (and at the lower surface).

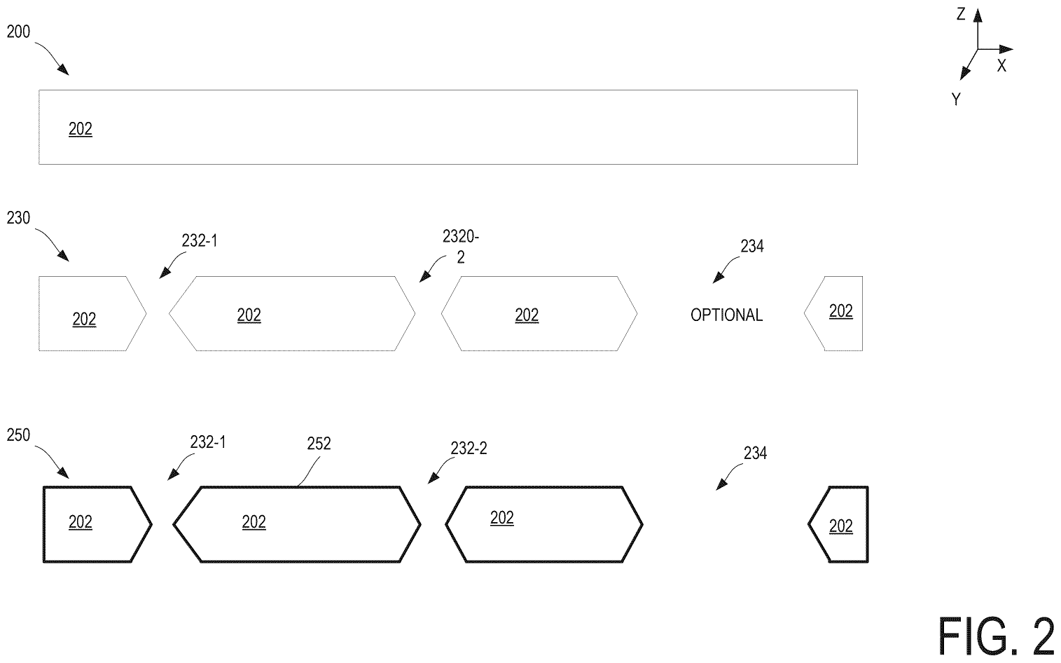

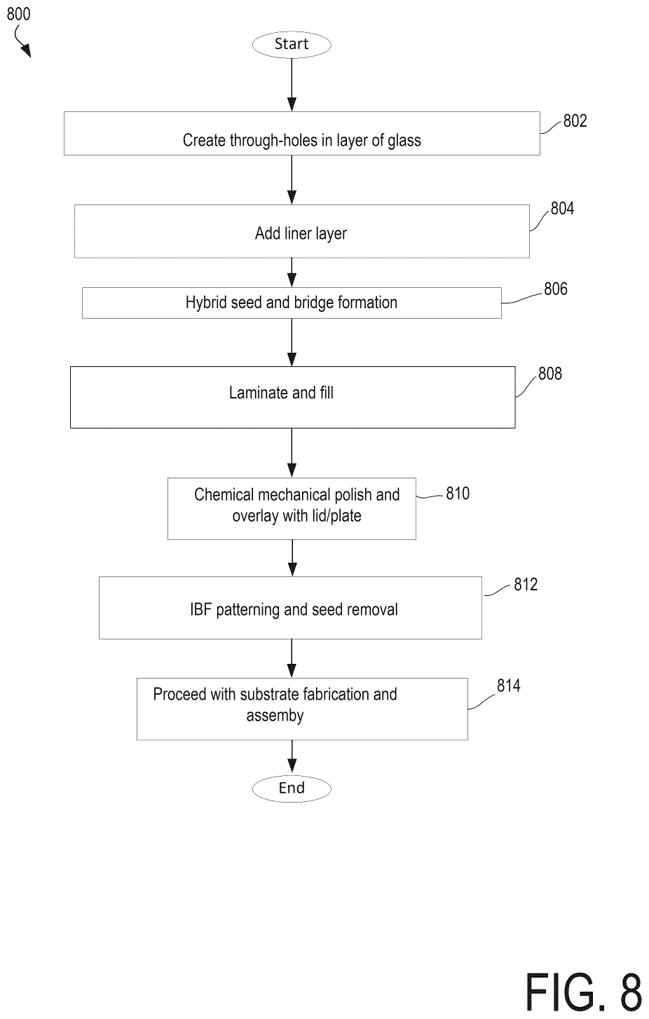

FIGS. 2-5 are simplified cross-sectional illustrations of various exemplary stages of fabrication of conformally plated through-glass vias, in accordance with various embodiments. FIGS. 6-7 are simplified cross-sectional illustrations of various exemplary use cases for conformally plated through-glass vias, in accordance with various embodiments. FIG. 8 illustrates an example method 800 for conformally plated through-glass vias.

Image 200 depicts a layer of glass 202 prior to creation of the TGVs and cavities. In embodiments that manufacture a panel at a time, the X length of a layer of glass, and a corresponding Y length (defining an area in a top down or plan view) may be in a range of a first length (e.g., X) in a range of 10 millimeters to 700 millimeters, and a second length (e.g., Y) in a range of 10 millimeters to 700 millimeters, the first length perpendicular to the second length. The composition of the glass 202 is described above in connection with FIG. 1.

Image 230 depicts (at 802) the through-holes or TGVs created in the layer of glass 202. As mentioned above, the laser changes the chemistry of the glass, allowing the area to be etched away preferentially, which results in a taper, as described in connection with embodiment 130. In image 230, the first TGV 232-1/330-1 and a second TGV 232-2/330-2 are illustrated. In practice, TGV 232-1 and 232-2 may be two of a plurality of TGVs. An optional cavity 234 may also be created at this stage. Optional cavity 234 may be large enough (e.g., minimum diameter 306) to fit an IC die or other component into at a later fabrication stage.

As shown in image 250, at 804 a liner layer 252 is added. The liner layer is adjacent to and conformal with the glass material in the layer of glass. The liner layer 252 can be anywhere between 15 nanometers and 10 microns thick. The thickness of the liner layer 252 depends on the method used to deposit it. Using a chemical vapor deposition (CVD) process, such as for silicon nitride, the liner layer 252 can be very thin, such as 20 nanometers+/−5 nanometers. In other embodiments, the liner can be a slit-coated dielectric material or a polymer, such as polyethylene, and then it could be between 50 nanometers and 10 microns with +/−10%.

Image 300 illustrates seed 302 deposited at 806. Seed is an initial layer of a conductive material 112 that is deposited across the upper surface and lower surface, and conformally into the TGVs and cavities to assist with electroplating. In various embodiments, the seed is copper. Some embodiments the seed 302 is a hybrid seed comprising layers, such as, ruthenium, then copper, then titanium, followed by copper. The hybrid seed may be deposited using CVD and the thickness 303 of the seed or hybrid seed layer may be 10 nanometers to 15 microns+/−10%. At 806, the bridges (bridge 116) are formed in the TGVs 330-1 and 330-2. The regions indicated by the dashed circles 304 are understood to have the features and orientations described in connection with FIG. 1, embodiment 130. In embodiments that include the optional cavity 332, those with skill in the art will appreciate that a bridge does not form across the diameter 306 because it is too large, e.g., cavity 332 can have a diameter a range between 1-30 millimeters.

The image 350 illustrates the layer of glass from 300 is laminated with an insulating material 352 (at 808). In various embodiments, the insulating material is a dielectric material. As illustrated, the cavities formed in the conductive material or seed 302 are filled at 808 with the insulating material 352. The optional cavity 332 is also filled with the insulating material. The dielectric material may have a thickness of 100 nanometers to 20 microns+/−10%.

The dielectric material may be any insulating material, such as, a suitable nitride or oxide, such as a SiOx, silicon dioxide (SiO₂), SiOxNy, carbon-doped silicon dioxide (C-doped SiO₂, also known as CDO or organosilicate glass, which is a material that comprises silicon, oxygen, and carbon), fluorine-doped silicon dioxide (F-doped SiO₂, also known as fluorosilicate glass, which is a material that comprises fluorine, silicon, and oxygen), hydrogen-doped silicon dioxide (H-doped SiO₂, which is a material that comprises silicon, oxygen, and hydrogen). In some embodiments, a dielectric layer comprises a photo-imageable dielectric (PID). In some embodiments, the dielectric material comprises an Ajinomoto Build-Up film (ABF), which is a material that comprises an organic resin matrix with different types of fillers (for example, silica fillers of different sizes, or hollow fillers of different sizes) to control the coefficient of thermal expansion (CTE) and/or electrical properties (e.g., the dielectric constant (Dk), and/or dissipation factor (insertion loss) (Df)).

In some embodiments, it is advantageous for the dielectric material to have a CTE that matches that of a component, such as an integrated circuit die, attached thereto (e.g., match the CTE of silicon) or to have a CTE that matches a substrate or PCB. In some embodiments, the dielectric material can have a CTE that is close (e.g., within 10%) to that of silicon. In other embodiments, the dielectric material can be any type of epoxy molding compound.

At 810 a chemical mechanical polish (CMP) may be performed to remove some of the insulating material to expose the conductive material 112 on the sidewall of the TGV, as well as exposing the about 20 microns+/−10% of the seed or conductive material 112, to promote electroplating in the next stage of fabrication. Upon completing the CMP process, a conductive plate 402 can be electrically attached across the planarized upper surface, as illustrated in image 400. In some embodiments, the conductive plate 402 comprises copper. Note that TGV 430-1 and TGV 430-2 now have the insulating material in the cavity, as does the larger optional cavity 432.

At 812, the conductive plate 402 is then patterned and etched to create a conductive contact or conductive pad for every TGV, for a subsequent via to land on and attach to. After the patterning and etching, the conductive plate 402 and seed 302 are removed accordingly, as illustrated in image 450. Note that the conductive contact 452-1 is electrically attached to the sidewall of TGV 430-1 at the upper surface, capping a cavity filled with the insulating material; and conductive contact 452-3 is also attached to the sidewall of TGV 430-1, at the lower surface, capping a cavity filled with the insulating material. Likewise, the conductive contact 452-2 is electrically attached to the sidewall of TGV 430-2 at the upper surface, capping a cavity filled with the insulating material; and conductive contact 452-4 is also attached to the sidewall of TGV 430-2, at the lower surface, capping a cavity filled with the insulating material. In some embodiments, the conductive contacts on the lower surface are referred to as conductive pads to distinguish them from those on the upper surface. Note that the optional cavity 432 is a region filled with the insulating material and has a sidewall 454 of the seed or hybrid seed. In practice the insulating material from this optional cavity 432 may be removed, such as by laser drilling or ablation, and an integrated circuit or component may be placed therein and electrically attached, e.g., in building a system or package assembly. This sidewall 454 (that may be surrounding an integrated circuit or other component) is an identifiable feature that indicates the practice of the methods and apparatus described herein.

Some non-limiting examples of ICs and components that may be placed in the cavity 432 include a memory or high bandwidth memory, trench capacitors, central processing unit, photonic integrated circuit, graphics processing unit, etc.

At 814 the layer of glass with the conformally plated TGVs may be subjected to further fabrication and assembly. In a simplified example, as shown in image 500, the embodiment from image 450 may have a silicon substrate built on its upper surface (e.g., at 504) or on its lower surface (e.g., at 506). Continuing with this simplified example, in image 600 and image 700, the embodiment from image 450 is shown attached to or sandwiched between, a substrate: the substrate 604/704 includes one or more dielectric layers 608/708 with redistribution layers (RDL) or conductive traces 628/728 and vias 626/726 patterned therein on the upper surface and substrate 606/706 includes one or more dielectric layers 608/708 with redistribution layers (RDL) or conductive traces 628 and vias 626 patterned therein on the lower surface.

The dielectric material may be one of the above-described dielectric materials or insulating materials. The conductive material used for RDL traces 628 and vias 626 may comprise a metal (e.g., copper, aluminum, nickel, cobalt, iron, tin, gold, silver, or combinations thereof) or another suitable conductive material.

The optional cavity 432 was opened and filled with an IC, PIC, or other component, and electrically attached at 610/710 and at 612/712, as known in the art. As intended, the provided conformally plated through-vias in the glass layer provide a landing and contact for vias and provide an electrical pathway from an upper surface 603/703 of the substrate to a lower surface 605/705 of the substrate.

In FIG. 7, a first IC and a second IC have been attached to the upper surface 703 and the lower surface 705 has had solder attached in the openings created for them. The die IC1 and IC 2, may be unpackaged integrated circuit die, and may alternatively be referred to as chips, chiplets, chip complexes, or chiplet complexes. While the terms die, chip, and chiplet may be used interchangeably, the term chiplet is sometimes used to refer to an integrated circuit die that implements a subset of the functionality of a larger integrated circuit component. Although the illustration depicts the chiplets as having uniform dimensions, in practice, chiplet dimensions (lateral dimensions, as well as thickness) and shape can vary among chiplets; moreover, the chiplets may vary by type/functionality (e.g., compute, memory, I/O, power management (controlling the delivery of power and/or providing power to components).

In further fabrication steps, the die IC 1 and IC 2 may be stabilized within an encapsulant such as a molding compound, dielectric materials, metal, ceramic, plastic, or a combination thereof. Also, an underfill may be employed below IC 1 and IC 2 to surround the solder bumps. A variety of underfill materials can be used, generally they are non-conducting (electrically) and reduce thermomechanical stress. Underfill materials may take the form of a liquid pre-polymer with a filler such as silica, alumina, or boron nitride. The underfill can be cured to solidify it.

Additionally, as part of a thermal management solution, a thermal conduction layer interface material (TIM) (not shown) may be located over the encapsulant and/or over the die. The TIM can be any suitable material, such as a silver particle-filled thermal compound, thermal grease, phase change materials, indium foils, or graphite sheets. The thermal management solution can be a conformal solution that accommodates differences in heights of the integrated circuit dies for which the thermal management solution provides cooling. For example, a thermal management solution can comprise a substantially planar cooling component with TIMs of varying thickness between the cooling component and the integrated circuit dies. In another example, the cooling component is non-planar, and the profile of the cooling component can vary with the thickness of the integrated circuit dies for which the cooling component provides cooling. In such embodiments, the TIM can be of substantially uniform thickness between the cooling component and the integrated circuit dies of varying thicknesses. Thermal management solutions can also include an integrated heat spreader.

Thus, various non-limiting embodiments of conformally plated through-vias in glass have been described. Embodiments exhibit distinct features in SEM images, not limited to: cavities inside TGVs that have insulating material in them, conductive material that varies in thickness along the TGV sidewall but holds a consistent planar cross-sectional area, bridges of conductive material in the midpoint of the TGV, and a wall of the conductive seed material around the periphery of a cavity housing an IC or other component. The following description provides additional details and context for various die and various package assembly and device configurations that can be created based on or using the provided embodiments.

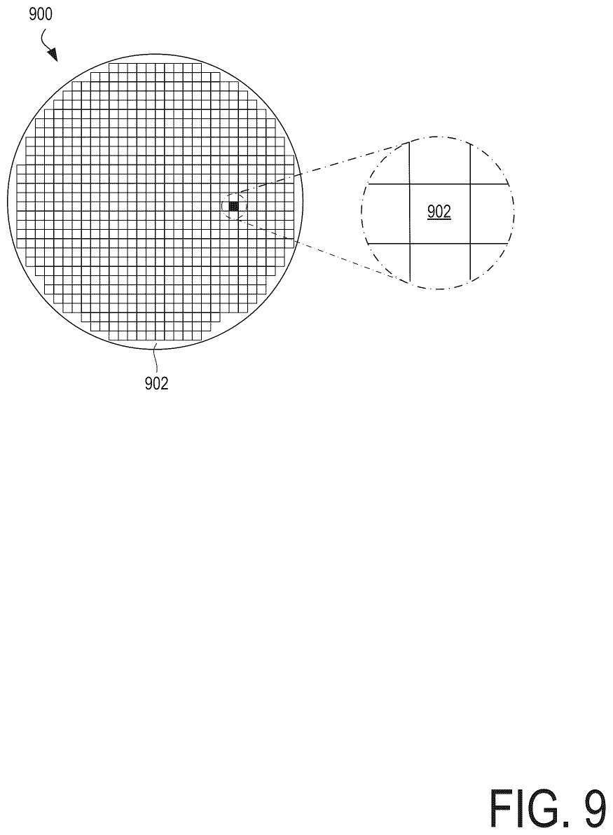

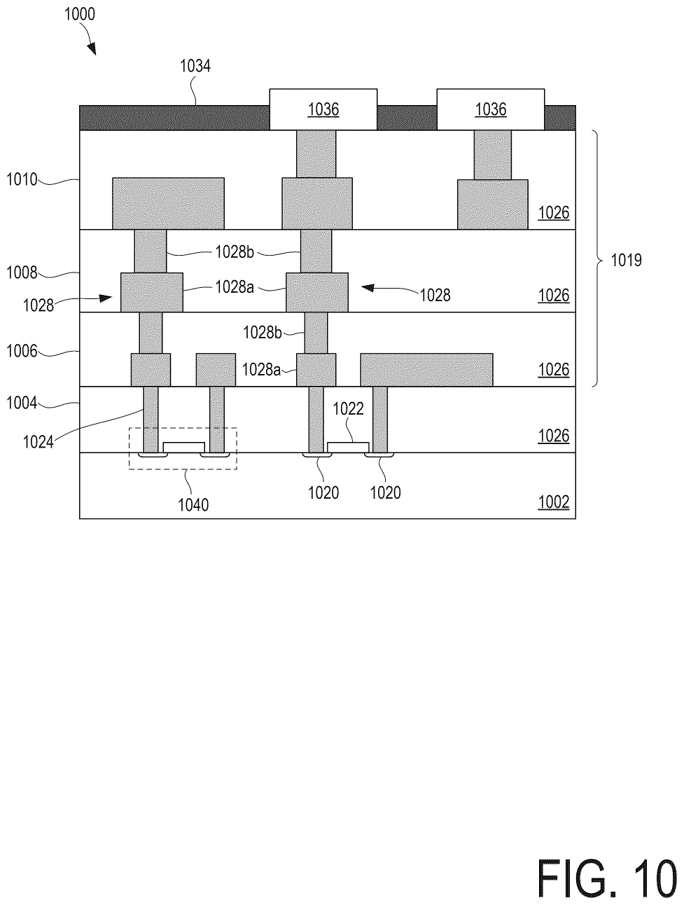

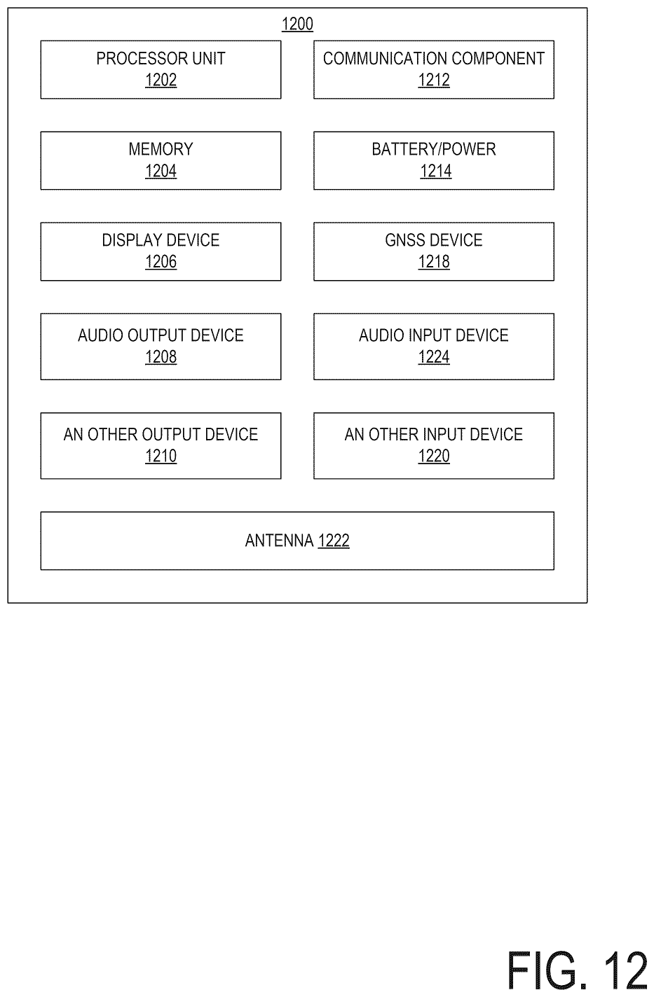

FIG. 9 is a top view of a wafer 900 and dies 902 that may be included in any of the embodiments disclosed herein. The wafer 900 may be composed of semiconductor material and may include one or more dies 902 formed on a surface of the wafer 900. After the fabrication of the integrated circuit components on the wafer 900 is complete, the wafer 900 may undergo a singulation process in which the dies 902 are separated from one another to provide discrete “chips” or destined for a packaged integrated circuit component. The individual dies 902, comprising an integrated circuit component, may include one or more transistors (e.g., some of the transistors 1040 of FIG. 10, discussed below), supporting circuitry to route electrical signals to the transistors, passive components (e.g., signal traces, resistors, capacitors, or inductors), and/or any other integrated circuit components. In some embodiments, the wafer 900 or the die 902 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Additionally, multiple devices may be combined on a single die 902. For example, a memory array formed by multiple memory devices may be formed on a same die 902 as a processor unit (e.g., the processor unit 1202 of FIG. 12) or other logic that is configured to store information in the memory devices or execute instructions stored in the memory array. In some embodiments, a die 902 may be attached to a wafer 900 that includes other die, and the wafer 900 is subsequently singulated, this manufacturing procedure is referred to as a die-to-wafer assembly technique.

FIG. 10 is a cross-sectional side view of an integrated circuit 1000 that may be included in any of the embodiments disclosed herein. One or more of the integrated circuits 1000 may be included in one or more dies 902 (FIG. 9). The integrated circuit 1000 may be formed on a die substrate 1002 (e.g., the wafer 900 of FIG. 9) and may be included in a die (e.g., the die 902 of FIG. 9).

The die substrate 1002 may be a semiconductor substrate composed of semiconductor material systems including, for example, n-type or p-type materials systems (or a combination of both). The die substrate 1002 may include, for example, a crystalline substrate formed using a bulk silicon or a silicon-on-insulator (SOI) substructure. In some embodiments, the die substrate 1002 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1002. Although a few examples of materials from which the die substrate 1002 may be formed are described here, any material that may serve as a foundation for an integrated circuit 1000 may be used. The die substrate 1002 may be part of a singulated die (e.g., the dies 902 of FIG. 9) or a wafer (e.g., the wafer 900 of FIG. 9).

The integrated circuit 1000 may include one or more device layers 1004 disposed on the die substrate 1002. The device layer 1004 may include features of one or more transistors 1040 (e.g., metal oxide semiconductor field-effect transistors (MOSFETs)) formed on the die substrate 1002. The transistors 1040 may include, for example, one or more source and/or drain (S/D) regions 1020, a gate 1022 to control current flow between the S/D regions 1020, and one or more S/D contacts 1024 to route electrical signals to/from the S/D regions 1020.

The gate 1022 may be formed of at least two layers, a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be conducted on the gate dielectric to improve its quality when a high-k material is used.

The gate electrode may be formed on the gate dielectric and may include at least one p-type work function metal or n-type work function metal, depending on whether the transistor 1040 is to be a p-type metal oxide semiconductor (PMOS) or an n-type metal oxide semiconductor (NMOS) transistor. In some implementations, the gate electrode may comprise a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1040 along the source-channel-drain direction, the gate electrode may comprise a U-shaped structure that includes a bottom portion substantially parallel to the surface of the die substrate 1002 and two sidewall portions that are substantially perpendicular to the top surface of the die substrate 1002. In other embodiments, at least one of the metal layers that form the gate electrode may simply be a planar layer that is substantially parallel to the top surface of the die substrate 1002 and does not include sidewall portions substantially perpendicular to the top surface of the die substrate 1002. In other embodiments, the gate electrode may comprise a combination of U-shaped structures and planar, non-U-shaped structures. For example, the gate electrode may comprise one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and include deposition and etching processes. In some embodiments, a plurality of spacer pairs may be used; for instance, two pairs, three pairs, or four pairs of sidewall spacers may be formed on opposing sides of the gate stack.

The S/D regions 1020 may be formed within the die substrate 1002 adjacent to the gate 1022 of individual transistors 1040. The S/D regions 1020 may be formed using an implantation/diffusion process or an etching/deposition process, for example. In the former process, dopants such as boron, aluminum, antimony, phosphorous, or arsenic may be ion-implanted into the die substrate 1002 to form the S/D regions 1020. An annealing process that activates the dopants and causes them to diffuse farther into the die substrate 1002 may follow the ion-implantation process. In the latter process, the die substrate 1002 may first be etched to form recesses at the locations of the S/D regions 1020. An epitaxial deposition process may then be conducted to fill the recesses with material that is used to fabricate the S/D regions 1020. In some implementations, the S/D regions 1020 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1020 may be formed using one or more alternate semiconductor materials such as germanium or a group III-V material or alloy. In further embodiments, one or more layers of metal and/or metal alloys may be used to form the S/D regions 1020.

Electrical signals, such as power and/or input/output (I/O) signals, may be routed to and/or from the devices (e.g., transistors 1040) of the device layer 1004 through one or more interconnect layers disposed on the device layer 1004 (illustrated in FIG. 10 as interconnect layers 1006-1010). For example, electrically conductive features of the device layer 1004 (e.g., the gate 1022 and the S/D contacts 1024) may be electrically coupled with the interconnect structures 1028 of the interconnect layers 1006-1010. The one or more interconnect layers 1006-1010 may form a metallization stack (also referred to as an “ILD stack”) 1019 of the integrated circuit 1000.

The interconnect structures 1028 may be arranged within the interconnect layers 1006-1010 to route electrical signals according to a wide variety of designs; in particular, the arrangement is not limited to the particular configuration of interconnect structures 1028 depicted in FIG. 10. Although a particular number of interconnect layers 1006-1010 is depicted in FIG. 10, embodiments of the present disclosure include integrated circuits having more or fewer interconnect layers than depicted.

In some embodiments, the interconnect structures 1028 may include lines 1028a and/or vias 1028b filled with an electrically conductive material such as a metal. The lines 1028a may be arranged to route electrical signals in a direction of a plane that is substantially parallel with a surface of the die substrate 1002 upon which the device layer 1004 is formed. For example, the lines 1028a may route electrical signals in a direction in and out of the page and/or in a direction across the page. The vias 1028b may be arranged to route electrical signals in a direction of a plane that is substantially perpendicular to the surface of the die substrate 1002 upon which the device layer 1004 is formed. In some embodiments, the vias 1028b may electrically couple lines 1028a of different interconnect layers 1006-1010 together.

The interconnect layers 1006-1010 may include a dielectric material 1026 disposed between the interconnect structures 1028, as shown in FIG. 10. In some embodiments, dielectric material 1026 disposed between the interconnect structures 1028 in different ones of the interconnect layers 1006-1010 may have different compositions; in other embodiments, the composition of the dielectric material 1026 between different interconnect layers 1006-1010 may be the same. The device layer 1004 may include a dielectric material 1026 disposed between the transistors 1040 and a bottom layer of the metallization stack as well. The dielectric material 1026 included in the device layer 1004 may have a different composition than the dielectric material 1026 included in the interconnect layers 1006-1010; in other embodiments, the composition of the dielectric material 1026 in the device layer 1004 may be the same as a dielectric material 1026 included in any one of the interconnect layers 1006-1010.

A first interconnect layer 1006 (referred to as Metal 1 or “M1”) may be formed directly on the device layer 1004. In some embodiments, the first interconnect layer 1006 may include lines 1028a and/or vias 1028b, as shown. The lines 1028a of the first interconnect layer 1006 may be coupled with contacts (e.g., the S/D contacts 1024) of the device layer 1004. The vias 1028b of the first interconnect layer 1006 may be coupled with the lines 1028a of a second interconnect layer 1008.

The second interconnect layer 1008 (referred to as Metal 2 or “M2”) may be formed directly on the first interconnect layer 1006. In some embodiments, the second interconnect layer 1008 may include via 1028b to couple the lines of interconnect structures 1028 of the second interconnect layer 1008 with the lines 1028a of a third interconnect layer 1010. Although the lines 1028a and the vias 1028b are structurally delineated with a line within individual interconnect layers for the sake of clarity, the lines 1028a and the vias 1028b may be structurally and/or materially contiguous (e.g., simultaneously filled during a dual-damascene process) in some embodiments.

The third interconnect layer 1010 (referred to as Metal 3 or “M3”) (and additional interconnect layers, as desired) may be formed in succession on the second interconnect layer 1008 according to similar techniques and configurations described in connection with the second interconnect layer 1008 or the first interconnect layer 1006. In some embodiments, the interconnect layers that are “higher up” in the metallization stack 1019 in the integrated circuit 1000 (i.e., farther away from the device layer 1004) may be thicker that the interconnect layers that are lower in the metallization stack 1019, with lines 1028a and vias 1028b in the higher interconnect layers being thicker than those in the lower interconnect layers.

The integrated circuit 1000 may include a solder resist material 1034 (e.g., polyimide or similar material) and one or more conductive contacts 1036 formed on the interconnect layers 1006-1010. In FIG. 10, the conductive contacts 1036 are illustrated as taking the form of bond pads. The conductive contacts 1036 may be electrically coupled with the interconnect structures 1028 and configured to route the electrical signals of the transistor(s) 1040 to external devices. For example, solder bonds may be formed on the one or more conductive contacts 1036 to mechanically and/or electrically couple an integrated circuit die including the integrated circuit 1000 with another component (e.g., a printed circuit board). The integrated circuit 1000 may include additional or alternate structures to route the electrical signals from the interconnect layers 1006-1010; for example, the conductive contacts 1036 may include other analogous features (e.g., posts) that route the electrical signals to external components.

In some embodiments in which the integrated circuit 1000 is a double-sided die, the integrated circuit 1000 may include another metallization stack (not shown) on the opposite side of the device layer(s) 1004. This metallization stack may include multiple interconnect layers as discussed above with reference to the interconnect layers 1006-1010, to provide electrically conductive paths (e.g., including conductive lines and vias) between the device layer(s) 1004 and additional conductive contacts (not shown) on the opposite side of the integrated circuit 1000 from the conductive contacts 1036.

In other embodiments in which the integrated circuit 1000 is a double-sided die, the integrated circuit 1000 may include one or more through-silicon vias (TSVs) through the die substrate 1002; these TSVs may make contact with the device layer(s) 1004, and may provide electrically conductive paths between the device layer(s) 1004 and additional conductive contacts (not shown) on the opposite side of the integrated circuit 1000 from the conductive contacts 1036. In some embodiments, TSVs extending through the substrate can be used for routing power and ground signals from conductive contacts on the opposite side of the integrated circuit 1000 from the conductive contacts 1036 to the transistors 1040 and any other components integrated into the integrated circuit 1000 die, and the metallization stack 1019 can be used to route I/O signals from the conductive contacts 1036 to transistors 1040 and any other components integrated into the integrated circuit 1000 die.

Multiple integrated circuits 1000 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

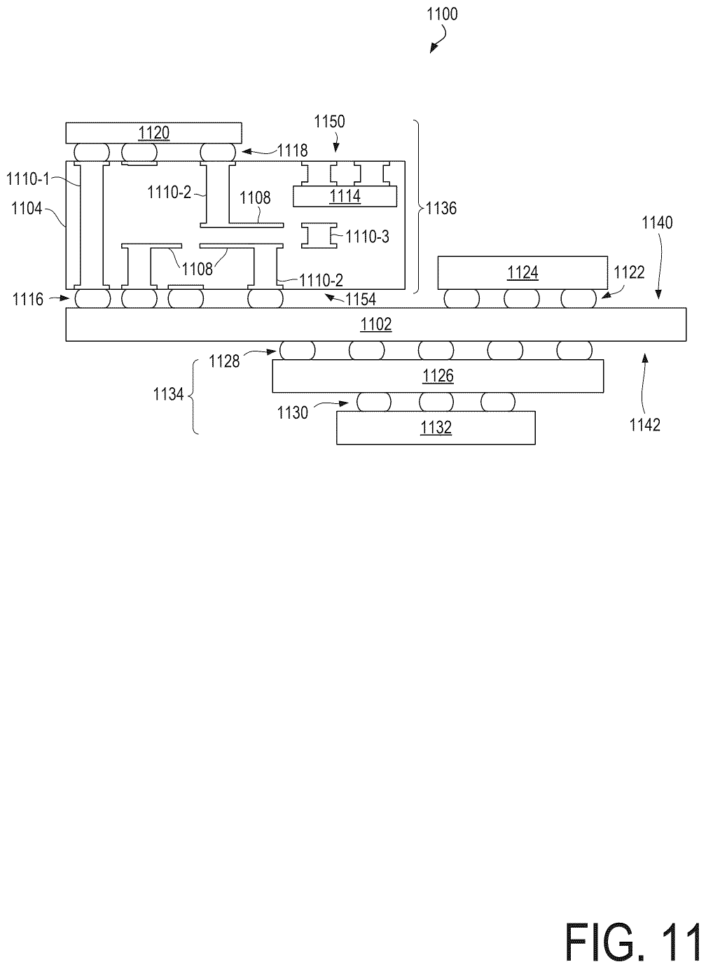

FIG. 11 is a cross-sectional side view of a microelectronic assembly 1100 that may include any of the embodiments disclosed herein. The microelectronic assembly 1100 includes multiple integrated circuit components disposed on a circuit board 1102 (which may be a motherboard, system board, mainboard, etc.). The microelectronic assembly 1100 may include components disposed on a first face 1140 of the circuit board 1102 and an opposing second face 1142 of the circuit board 1102; generally, components may be disposed on one or both faces 1140 and 1142.

In some embodiments, the circuit board 1102 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1102. In other embodiments, the circuit board 1102 may be a non-PCB substrate. The microelectronic assembly 1100 illustrated in FIG. 11 includes a package-on-interposer structure 1136 coupled to the first face 1140 of the circuit board 1102 by coupling components 1116. The coupling components 1116 may electrically and mechanically couple the package-on-interposer structure 1136 to the circuit board 1102, and may include solder balls (as shown in FIG. 11), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 1136 may include an integrated circuit component 1120 coupled to an interposer 1104 by coupling components 1118. The coupling components 1118 may take any suitable form for the application, such as the forms discussed above with reference to the coupling components 1116. Although a single integrated circuit component 1120 is shown in FIG. 11, multiple integrated circuit components may be coupled to the interposer 1104; indeed, additional interposers may be coupled to the interposer 1104. The interposer 1104 may provide an intervening substrate used to bridge the circuit board 1102 and the integrated circuit component 1120.

The integrated circuit component 1120 may be a packaged or unpackaged integrated circuit component that includes one or more integrated circuit dies (e.g., the die 902 of FIG. 9, the integrated circuit 1000 of FIG. 10) and/or one or more other suitable components.

The unpackaged integrated circuit component 1120 comprises solder bumps attached to contacts on the die. The solder bumps allow the die to be directly attached to the interposer 1104. In embodiments where the integrated circuit component 1120 comprises multiple integrated circuit die, the dies can be of the same type (a homogeneous multi-die integrated circuit component) or of two or more different types (a heterogeneous multi-die integrated circuit component). In addition to comprising one or more processor units, the integrated circuit component 1120 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate, or combinations thereof. A packaged multi-die integrated circuit component can be referred to as a multi-chip package (MCP) or multi-chip module (MCM).

The interposer 1104 may spread connections to a wider pitch or reroute a connection to a different connection. For example, the interposer 1104 may couple the integrated circuit component 1120 to a set of ball grid array (BGA) conductive contacts of the coupling components 1116 for coupling to the circuit board 1102. In the embodiment illustrated in FIG. 11, the integrated circuit component 1120 and the circuit board 1102 are attached to opposing sides of the interposer 1104; in other embodiments, the integrated circuit component 1120 and the circuit board 1102 may be attached to a same side of the interposer 1104. In some embodiments, three or more components may be interconnected by way of the interposer 1104.

In some embodiments, the interposer 1104 may be formed as a PCB, including multiple metal layers separated from one another by layers of dielectric material and interconnected by electrically conductive vias. In some embodiments, the interposer 1104 may be formed of an epoxy resin, a fiberglass-reinforced epoxy resin, an epoxy resin with inorganic fillers, a ceramic material, or a polymer material such as polyimide. In some embodiments, the interposer 1104 may be formed of alternate rigid or flexible materials that may include the same materials described above for use in a semiconductor substrate, such as silicon, germanium, and other group III-V and group IV materials. The interposer 1104 may include metal interconnects 1108 and vias 1110, including but not limited to through hole vias 1110-1 (that extend from a first face 1150 of the interposer 1104 to a second face 1154 of the interposer 1104), blind vias 1110-2 (that extend from the first or second faces 1150 or 1154 of the interposer 1104 to an internal metal layer), and buried vias 1110-3 (that connect internal metal layers).

In some embodiments, the interposer 1104 can comprise a silicon interposer. Through-silicon vias (TSV) extending through the silicon interposer can connect connections on the first face of a silicon interposer to an opposing second face of the silicon interposer. In some embodiments, an interposer 1104 comprising a silicon interposer can further comprise one or more routing layers to route connections on a first face of the interposer 1104 to an opposing second face of the interposer 1104.

The interposer 1104 may further include embedded devices 1114, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1104. The package-on-interposer structure 1136 may take the form of any of the package-on-interposer structures known in the art.

The integrated circuit assembly 1100 may include an integrated circuit component 1124 coupled to the first face 1140 of the circuit board 1102 by coupling components 1122. The coupling components 1122 may take the form of any of the embodiments discussed above with reference to the coupling components 1116, and the integrated circuit component 1124 may take the form of any of the embodiments discussed above with reference to the integrated circuit component 1120.

The integrated circuit assembly 1100 illustrated in FIG. 11 includes a package-on-package structure 1134 coupled to the second face 1142 of the circuit board 1102 by coupling components 1128. The package-on-package structure 1134 may include an integrated circuit component 1126 and an integrated circuit component 1132 coupled together by coupling components 1130 such that the integrated circuit component 1126 is disposed between the circuit board 1102 and the integrated circuit component 1132. The coupling components 1128 and 1130 may take the form of any of the embodiments of the coupling components 1116 discussed above, and the integrated circuit components 1126 and 1132 may take the form of any of the embodiments of the integrated circuit component 1120 discussed above. The package-on-package structure 1134 may be configured in accordance with any of the package-on-package structures known in the art.

FIG. 12 is a block diagram of an example electrical device 1200 that may include one or more of the embodiments disclosed herein. For example, any suitable ones of the components of the electrical device 1200 may include one or more of the microelectronic assemblies 1100, integrated circuit components 1120, integrated circuits 1000, integrated circuit dies 902, or structures disclosed herein. A number of components are illustrated in FIG. 12 as included in the electrical device 1200, but any one or more of these components may be omitted or duplicated, as suitable for the application. In some embodiments, some or all the components included in the electrical device 1200 may be attached to one or more motherboards, mainboards, printed circuit boards, or system boards. In some embodiments, one or more of these components are fabricated onto a single system-on-a-chip (SoC) die. In various embodiments, the electrical device 3000 is enclosed by, or integrated with, a housing.

Additionally, in various embodiments, the electrical device 1200 may not include one or more of the components illustrated in FIG. 12, but the electrical device 1200 may include interface circuitry for coupling to the one or more components. For example, the electrical device 1200 may not include a display device 1206, but may include display device interface circuitry (e.g., a connector and driver circuitry) to which a display device 1206 may be coupled. In another set of examples, the electrical device 1200 may not include an audio input device 1224 or an audio output device 1208, but may include audio input or output device interface circuitry (e.g., connectors and supporting circuitry) to which an audio input device 1224 or audio output device 1208 may be coupled.

The electrical device 1200 may include one or more processor units 1202 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1202 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller crypto processors (specialized processors that execute cryptographic algorithms within hardware), server processors, controllers, or any other suitable type of processor units. As such, the processor unit can be referred to as an XPU (or xPU).

The electrical device 1200 may include a memory 1204, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1204 may include memory that is located on the same integrated circuit die as the processor unit 1202. This memory may be used as cache memory (e.g., Level 1 (L1), Level 2 (L2), Level 3 (L3), Level 4 (L4), Last Level Cache (LLC)) and may include embedded dynamic random-access memory (eDRAM) or spin transfer torque magnetic random-access memory (STT-MRAM).

In some embodiments, the electrical device 1200 can comprise one or more processor units 1202 that are heterogeneous or asymmetric to another processor unit 1202 in the electrical device 1200. There can be a variety of differences between the processor units 1202 in a system in terms of a spectrum of metrics of merit including architectural, microarchitectural, thermal, power consumption characteristics, and the like. These differences can effectively manifest themselves as asymmetry and heterogeneity among the processor units 1202 in the electrical device 1200.

In some embodiments, the electrical device 1200 may include a communication component 1212 (e.g., one or more communication components). For example, the communication component 1212 can manage wireless communications for the transfer of data to and from the electrical device 1200. The term “wireless” and its derivatives may be used to describe circuits, devices, systems, methods, techniques, communications channels, etc., that may communicate data using modulated electromagnetic radiation through a nonsolid medium. The term “wireless” does not imply that the associated devices do not contain any wires, although in some embodiments they might not.

The communication component 1212 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra-mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1212 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1212 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1212 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1212 may operate in accordance with other wireless protocols in other embodiments. The electrical device 1200 may include an antenna 1222 to facilitate wireless communications and/or to receive other wireless communications (such as AM or FM radio transmissions).

In some embodiments, the communication component 1212 may manage wired communications, such as electrical, optical, or any other suitable communication protocols (e.g., IEEE 802.3 Ethernet standards). As noted above, the communication component 1212 may include multiple communication components. For instance, a first communication component 1212 may be dedicated to shorter-range wireless communications such as Wi-Fi or Bluetooth, and a second communication component 1212 may be dedicated to longer-range wireless communications such as global positioning system (GPS), EDGE, GPRS, CDMA, WiMAX, LTE, EV-DO, or others. In some embodiments, a first communication component 1212 may be dedicated to wireless communications, and a second communication component 1212 may be dedicated to wired communications.

The electrical device 1200 may include battery/power circuitry 1214. The battery/power circuitry 1214 may include one or more energy storage devices (e.g., batteries or capacitors) and/or circuitry for coupling components of the electrical device 1200 to an energy source separate from the electrical device 1200 (e.g., AC line power).

The electrical device 1200 may include a display device 1206 (or corresponding interface circuitry, as discussed above). The display device 1206 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1200 may include an audio output device 1208 (or corresponding interface circuitry, as discussed above). The audio output device 1208 may include any embedded or wired or wirelessly connected external device that generates an audible indicator, such speakers, headsets, or earbuds.

The electrical device 1200 may include an audio input device 1224 (or corresponding interface circuitry, as discussed above). The audio input device 1224 may include any embedded or wired or wirelessly connected device that generates a signal representative of a sound, such as microphones, microphone arrays, or digital instruments (e.g., instruments having a musical instrument digital interface (MIDI) output). The electrical device 1200 may include a Global Navigation Satellite System (GNSS) device 1218 (or corresponding interface circuitry, as discussed above), such as a Global Positioning System (GPS) device. The GNSS device 1218 may be in communication with a satellite-based system and may determine a geolocation of the electrical device 1200 based on information received from one or more GNSS satellites, as known in the art.

The electrical device 1200 may include another output device 1210 (or corresponding interface circuitry, as discussed above). Examples of the other output device 1210 may include an audio codec, a video codec, a printer, a wired or wireless transmitter for providing information to other devices, or an additional storage device.

The electrical device 1200 may include another input device 1220 (or corresponding interface circuitry, as discussed above). Examples of the other input device 1220 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1200 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra-mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1200 may be any other electronic device that processes data. In some embodiments, the electrical device 1200 may comprise multiple discrete physical components. Given the range of devices that the electrical device 1200 can be manifested as in various embodiments, in some embodiments, the electrical device 1200 can be referred to as a computing device or a computing system.

While at least one embodiment has been presented in the foregoing detailed description, it should be appreciated that a vast number of variations exist. It should also be appreciated that the disclosed embodiments are only examples, and are not intended to limit the scope, applicability, or configuration of the disclosure in any way. Rather, the foregoing detailed description will provide those skilled in the art with a convenient road map for implementing the disclosed embodiment embodiments. Various changes can be made in the function and arrangement of elements without departing from the scope of the disclosure as set forth in the appended claims and the legal equivalents thereof.

As used herein, the term “electronic component” can refer to an active electronic circuit (e.g., processing unit, memory, storage device, FET) or a passive electronic circuit (e.g., resistor, inductor, capacitor).

As used herein, the term and “integrated circuit component” can refer to an electronic component configured on a semiconducting material to perform a function. An integrated circuit (IC) component can comprise one or more of any computing system components described or referenced herein or any other computing system component, such as a processor unit (e.g., system-on-a-chip (SoC), processor core, graphics processor unit (GPU), accelerator, chipset processor), I/O controller, memory, or network interface controller, and can comprise one or more additional active or passive devices such as capacitors, decoupling capacitors, resistors, inductors, fuses, diodes, transformers, sensors, electrostatic discharge (ESD) devices, and memory devices.

A non-limiting example of an unpackaged integrated circuit component includes a single monolithic integrated circuit die; the die may include solder bumps attached to contacts on the die. When present on the die, the solder bumps or other conductive contacts can enable the die to be directly attached to a printed circuit board (PCB) or other substrates.

A non-limiting example of a packaged integrated circuit component comprises one or more integrated circuit dies mounted on a package substrate with the integrated circuit dies and package substrate encapsulated in a casing material, such as a metal, plastic, glass, or ceramic. Often the casing includes an integrated heat spreader (IHS); the packaged integrated circuit component often has bumps, leads, or pins attached to the package substrate (either directly or by wires attaching the bumps, leads, or pins to the package substrate) for attaching the packaged integrated circuit component to a printed circuit board (or motherboard or base board) or another component.

As used herein, phrases such as “an embodiment,” “various embodiments,” “some embodiments,” and the like, indicate that some embodiments may have some, all, or none of the features described for other embodiments. “First,” “second,” “third,” and the like describe a common object and indicate different instances of like objects being referred to; unless specifically stated, they do not imply a given sequence, either temporally or spatially, in ranking, or any other manner. In accordance with patent application parlance, “connected” indicates elements that are in direct physical or electrical contact with each other and “coupled” indicates elements that co-operate or interact with each other, coupled elements may or may not be in direct physical or electrical contact. Furthermore, the terms “comprising,” “including,” “having,” and the like, are utilized synonymously to denote non-exclusive inclusions.

As used in this application and the claims, a list of items joined by the term “at least one of” or the term “one or more of” can mean any combination of the listed terms. For example, the phrase “at least one of A, B or C” can mean A; B; C; A and B; A and C; B and C; or A, B, and C. Likewise, the phrase “one or more of A, B and C” can mean A; B; C; A and B; A and C; B and C; or A, B, and C.

As used in this application and the claims, the phrase “individual of” or “respective of” following by a list of items recited or stated as having a trait, feature, etc., means that all the items in the list possess the stated or recited trait, feature, etc. For example, the phrase “individual of A, B, or C, comprise a sidewall” or “respective of A, B, or C, comprise a sidewall” means that A comprises a sidewall, B comprises sidewall, and C comprises a sidewall.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

The following examples pertain to additional embodiments of technologies disclosed herein.

### EXAMPLES

Example 1 is an apparatus comprising: a layer of glass defined by an upper surface and a lower surface; a through-hole formed in the layer of glass, extending downward from the upper surface to the lower surface, with an axis that is orthogonal to the upper surface; the through-hole characterized by a sidewall with a first diameter at the upper surface and the first diameter at the lower surface; a conductive material conformal to the sidewall from the upper surface to the lower surface and defining a cavity therein; an insulating material in the cavity; and a conductive contact extending across the through-hole at the upper surface and electrically connected to the conductive material.

Example 2 includes the subject matter of Example 1, wherein the cavity extends from the upper surface to the lower surface, and the insulating material is continuous from the upper surface to the lower surface.

Example 3 includes the subject matter of Example 1, wherein the through-hole is further characterized by a second diameter in between the upper surface and the lower surface, the second diameter is at least 20% smaller than the first diameter.

Example 4 includes the subject matter of any one of Examples 1-3, wherein the conductive material comprises a cross-sectional area, measured perpendicular to the axis, and between the upper surface and the lower surface, the cross-sectional area varies by less than 10%.

Example 5 includes the subject matter of any one of Examples 1, 3, or 4, wherein the conductive material comprises a thickness, measured orthogonal from the sidewall, and wherein the thickness at the upper surface and the lower surface is at least 20% less than the thickness at a midpoint between the upper surface and the lower surface.

Example 6 includes the subject matter of Example 5, further comprising a bridge formed by the conductive material between the upper surface and the lower surface.

Example 7 includes the subject matter of Example 6, wherein the bridge forms a floor to the cavity and creates an additional cavity between the bridge and the lower surface; and further comprising the insulating material in the additional cavity.

Example 8 includes the subject matter of Example 1 or Example 7, further comprising a conductive pad extending across the through-hole on the lower surface, and electrically connected to the conductive material.

Example 9 includes the subject matter of any one of Examples 1-8, wherein the conductive material comprises a layer of ruthenium, then a layer of copper, then a layer of titanium, followed by a layer of copper.

Example 10 includes the subject matter of any one of Examples 1-8, wherein the conductive material and the conductive contact comprises copper.

Example 11 includes the subject matter of any one of Examples 1-10, wherein the insulating material is a dielectric material.

Example 12 is a semiconductor package, comprising: a semiconductor substrate including a plurality of dielectric layers and redistribution layers therein; a conductive via in the semiconductor substrate, the conductive via electrically connected to a redistribution layer and exposed at a lower surface of the semiconductor substrate; a layer of glass attached to the lower surface of the semiconductor substrate, the layer of glass comprising a plurality of through-glass vias; wherein the through-glass vias comprise tapered sidewalls that are conformally plated with a conductive material; wherein, in the tapered sidewalls, the conductive material forms a respective cavity with an insulating material therein; a conductive contact on the layer of glass, the conductive contact extending across a through-glass via; and wherein the conductive via is electrically attached to the conductive contact.

Example 13 includes the subject matter of Example 12, wherein, in the tapered sidewalls, the conductive material forms a bridge in the through-glass via.

Example 14 includes the subject matter of Example 12 or Example 13, wherein, in the tapered sidewalls, the conductive material has a first thickness at an upper surface of the layer of glass and a second thickness that is larger than the first thickness at a midpoint between the upper surface and a lower surface of the layer of glass.

Example 15 includes the subject matter of Example 12 or Example 13, wherein the through-glass vias are formed around an axis that is orthogonal to an upper surface of the layer of glass; wherein, in the tapered sidewalls, the conductive material comprises a cross-sectional area, measured perpendicular to the axis; and between the upper surface and the lower surface, the cross-sectional area of the conductive material in a TGV varies by less than 10%.

Example 16 includes the subject matter of any one of Examples 12-15, further comprising: an integrated circuit die attached on an upper surface of the semiconductor substrate; and an electrical pathway from the integrated circuit die through a through-glass via of the plurality of through glass vias to a lower surface of the layer of glass.

Example 17 is a method, comprising: creating through-glass vias (TGVs) in a layer of glass; depositing a liner layer on the layer of glass with the TGVs; depositing, over the liner layer, a hybrid layer comprising ruthenium, then copper, then titanium, followed by copper; causing the hybrid layer to form, in the TGVs, a cavity with a bridge therein; laminating a dielectric material on the hybrid layer; and causing the dielectric material to fill, in the TGVs, at least part of the cavity above the bridge.

Example 18 includes the subject matter of Example 17, further comprising: removing the dielectric material to expose the hybrid layer; attaching a conductive plate to the hybrid layer; and etching the conductive plate to create, for individual TGVs, a respective conductive contact.

Example 19 includes the subject matter of Example 18, further comprising attaching a first silicon substrate to an upper surface of the layer of glass, and a second silicon substrate to a lower surface of the layer of glass.

Example 20 includes the subject matter of Example 19, further comprising attaching an integrated circuit (IC) die to the first silicon substrate and creating an electrical pathway from the IC die to a conductive contact on a lower surface of the second silicon substrate.

What is claimed is:

1. An apparatus comprising:
a layer of glass defined by an upper surface and a lower surface;
a through-hole formed in the layer of glass, extending downward from the upper surface to the lower surface, with an axis that is orthogonal to the upper surface;
the through-hole characterized by a sidewall with a first diameter at the upper surface and the first diameter at the lower surface;
a conductive material conformal to the sidewall from the upper surface to the lower surface and defining a cavity therein;
an insulating material in the cavity; and
a conductive contact extending across the through-hole at the upper surface and electrically connected to the conductive material.

2. The apparatus of claim 1, wherein the cavity extends from the upper surface to the lower surface, and the insulating material is continuous from the upper surface to the lower surface.

3. The apparatus of claim 1, wherein the through-hole is further characterized by a second diameter in between the upper surface and the lower surface, the second diameter is at least 20% smaller than the first diameter.

4. The apparatus of claim 1, wherein the conductive material comprises a cross-sectional area, measured perpendicular to the axis, and between the upper surface and the lower surface, the cross-sectional area varies by less than 10%.

5. The apparatus of claim 1, wherein the conductive material comprises a thickness, measured orthogonal from the sidewall, and wherein the thickness at the upper surface and the lower surface is at least 20% less than the thickness at a midpoint between the upper surface and the lower surface.

6. The apparatus of claim 1, further comprising a bridge formed by the conductive material between the upper surface and the lower surface.

7. The apparatus of claim 6, wherein the bridge forms a floor to the cavity and creates an additional cavity between the bridge and the lower surface; and
further comprising the insulating material in the additional cavity.

8. The apparatus of claim 7, further comprising a conductive pad extending across the through-hole on the lower surface, and electrically connected to the conductive material.

9. The apparatus of claim 1, wherein the conductive material comprises a layer of ruthenium, then a layer of copper, then a layer of titanium, followed by a layer of copper.

10. The apparatus of claim 1, wherein the conductive material and the conductive contact comprises copper.

11. The apparatus of claim 1, wherein the insulating material is a dielectric material.

12. A semiconductor package, comprising:
a semiconductor substrate including a plurality of dielectric layers and redistribution layers therein;
a conductive via in the semiconductor substrate, the conductive via electrically connected to a redistribution layer and exposed at a lower surface of the semiconductor substrate;
a layer of glass attached to the lower surface of the semiconductor substrate, the layer of glass comprising a plurality of through-glass vias;
wherein the through-glass vias comprise tapered sidewalls that are conformally plated with a conductive material;
wherein, in the tapered sidewalls, the conductive material forms a respective cavity with an insulating material therein; and
a conductive contact on the layer of glass, the conductive contact extending across a through-glass via;
wherein the conductive via is electrically attached to the conductive contact.

13. The semiconductor package of claim 12, wherein, in the tapered sidewalls, the conductive material forms a bridge in the through-glass via.

14. The semiconductor package of claim 12, wherein, in the tapered sidewalls, the conductive material has a first thickness at an upper surface of the layer of glass and a second thickness that is larger than the first thickness at a midpoint between the upper surface and a lower surface of the layer of glass.

15. The semiconductor package of claim 12, wherein the through-glass vias are formed around an axis that is orthogonal to an upper surface of the layer of glass;
wherein, in the tapered sidewalls, the conductive material comprises a cross-sectional area, measured perpendicular to the axis; and
between the upper surface and the lower surface, the cross-sectional area of the conductive material in a TGV varies by less than 10%.

16. The semiconductor package of claim 12, further comprising:
an integrated circuit die attached on an upper surface of the semiconductor substrate; and
an electrical pathway from the integrated circuit die through a through-glass via of the plurality of through glass vias to a lower surface of the layer of glass.

17. A method, comprising:
creating through-glass vias (TGVs) in a layer of glass;
depositing a liner layer on the layer of glass with the TGVs;
depositing, over the liner layer, a hybrid layer comprising ruthenium, then copper, then titanium, followed by copper;
causing the hybrid layer to form, in the TGVs, a cavity with a bridge therein;
laminating a dielectric material on the hybrid layer; and
causing the dielectric material to fill, in the TGVs, at least part of the cavity above the bridge.

18. The method of claim 17, further comprising:
removing the dielectric material to expose the hybrid layer;
attaching a conductive plate to the hybrid layer; and
etching the conductive plate to create, for individual TGVs, a respective conductive contact.

19. The method of claim 18, further comprising attaching a first silicon substrate to an upper surface of the layer of glass, and a second silicon substrate to a lower surface of the layer of glass.

20. The method of claim 19, further comprising attaching an integrated circuit (IC) die to the first silicon substrate and creating an electrical pathway from the IC die to a conductive contact on a lower surface of the second silicon substrate.
